(19) United States
(12) Patent Application Publication
(10) Pub. No.: US 2013/0014983 A1
(43) Pub. Date: Jan. 17, 2013

(54) DEVICE CONTACTOR WITH INTEGRATED RF SHIELD

(71) Applicants: Michael Patrick Korson, Plano, TX (US); David Walker Guidry, Rowlett, TX (US)

(72) Inventors: Michael Patrick Korson, Plano, TX (US); David Walker Guidry, Rowlett, TX (US)

(73) Assignee: Texas Instruments Incorporated

(21) Appl. No.: 13/182,795

(22) Filed: Jul. 14, 2011

(51) Int. Cl. H05K 9/00

(52) U.S. Cl. 174/378; 174/377

(57) ABSTRACT

An apparatus includes a device contactor having an integrated radio frequency (“RF”) shield and a gasket coupled to a first surface of the device contactor. When the device contactor is removably attached to a printed circuit board (“PCB”), the gasket contacts the PCB, and the RF shield and the gasket form a Faraday cage that shields a device under test and/or circuitry associated with the device under test from RF noise.

### FIELD OF THE INVENTION

This invention relates generally to the field of semiconductor devices and device testing, and more particularly, to methods and apparatus for shielding a device under test and nearby circuitry from noise and interference.

### DESCRIPTION OF THE RELATED ART

In testing or measuring electrical properties of integrated circuit (“IC”) devices in a post-production stage, each IC device is connected to an IC tester through a load board electrically connected to respective electrodes of the IC device. For this purpose, one or more device contactors are typically mounted on the load board and serve as part of a contacting mechanism for IC devices under test. During a test, IC devices are coupled to the device contactors to electrically connect the IC devices to the IC tester.

Existing device contactor designs do not completely shield a device under test and nearby circuitry on a load board from radio frequency (“RF”) and electromagnetic (“EM”) interference, such as external signals and radiation from mobile phones and other RF sources. This lack of shielding allows external radiation to interfere with the device and circuitry under sensitive tests during production, such as the noise figure test, thus adversely impacting test results on the load board.

An existing practice involves the use of a metal body contactor. However, a metal body contactor does not seal all possible entry points for external radiation. Another existing practice involves disposing a conductive/dissipative material over an encapsulating insulative material and an integrated circuit (“IC”) chip atop a substrate, to provide a completely sealed and shielded packaged IC chip. However, the conductive/dissipative material is permanently disposed over the IC chip and cannot be operationally removed.

### SUMMARY OF THE INVENTION

Applicants have recognized that there is a need for methods and apparatus for shielding a device under test and nearby circuitry on a printed circuit board (“PCB”), such as a load board, from RF and EM interference. Applicants have also recognized that an RF shield directly coupled to a PCB does not fully seal all possible entry points for external radiation. Applicants have further recognized that a permanent coating of conductive/dissipative material over a device, in addition to shielding only the device and not the nearby circuitry, cannot be reused for testing other devices and their associated circuitry. Therefore, it is a technical advantage to provide an RF shield operationally attached to a device contactor instead of a device, such that when the device contactor is docked or removably attached to a PCB, the RF shield forms a Faraday cage. It is a further technical advantage to incorporate a conductive shield gasket operationally attached to the device contactor, to seal all possible entry points for external radiation when the device contactor is docked or attached to a PCB.

An initial attempt to address external RF and EM interference that plagued integrated circuit (“IC”) devices under test involved attaching copper foil and tape as a makeshift shield around a device contactor. While the copper foil reduced RF and EM noise penetration, the foil did not facilitate an easy removal and a complete seal, and thus left some gaps through which RF and EM noise could still affect the devices under test. Moreover, the copper foil was too thin to fully shield the devices under test, even within space covered by the copper foil.

Applicants recognized that a machined RF shield, instead of a makeshift shield made of copper foil, would improve noise shielding and be more durable. Applicants also recognized that the RF shield can be integrated with a device contactor to form a reusable Faraday cage for a device under test. While experimenting with the RF shield, Applicants further recognized that a compressible RF gasket material can be operationally attached to the device contactor to form a more complete seal between the RF shield and the PCB when the device contactor is docked or removably attached to the PCB, thus sealing off most if not all possible entry points for external radiation that may interfere with the device under test. Applicants noted that by operationally attaching the RF gasket material to the device contactor, the RF gasket material becomes reusable for testing other devices because when the device contactor is removed from the PCB, the RF gasket material remains attached to the device contactor instead of the PCB. Moreover, the RF gasket material, if conductive, can mate the RF shield to the ground plane on the PCB. Through further experimentation, Applicants came up with machined grooves in the device contactor to house and/or seat the RF gasket material.

In this manner, a device contactor can integrate RF gasket material in the device contactor's PCB attachment points. When the device contactor is docked or removably attached to a PCB, the RF gasket material helps the device contactor to form a Faraday cage that more fully shields a device under test and/or the device's associated circuitry. The attachment points for the RF gasket material can be located on a PCB-facing surface of the device contactor. For example, the attachment points can be located along or near the outer edges or periphery of a PCB-facing surface of the device contactor, thus maximizing the volume of the Faraday cage. For another example, the attachment points can be located through an interior of the device contractor's PCB-facing surface, to shield a device under test from its associated circuitry and vice versa, or if the device contactor hosts multiple devices under test, to minimize cross-talk by shielding the devices from one another and/or their associated circuitry.

The device contactor can be made of a conductive material(s), such as metals and metal alloys, semimetals (e.g., graphite), conductive polymers, and the like. The device contactor can also be made of other types of material, such as plastic, ceramic, anodized metal, and the like, and can contain or be coated with conductive materials. The RF gasket material can be compressible and conductive so that when the device contactor is docked or attached to the PCB, the RF gasket material can seal gaps between the device contactor and the PCB and form a good ground connection to the PCB. The RF gasket material can be made of a compressible conductive material(s), such as conductive elastomers, compressible resins, filled plastics, knitted wire mesh, fabric over foam, and the like.

Integrating an RF shield to a device contactor forms a Faraday cage that improves noise shielding for a device under test and circuitry associated with the device. Integrating a machined RF shield forms a reusable and durable Faraday cage operationally attached to the device contactor, which results in enhanced noise shielding, improved test results, and greater processing flexibility. Incorporating an RF gasket material operationally attached to a device contactor's PCB attachment points enhances noise shielding when the device contactor is docked or attached to a PCB. Moreover, the RF gasket material, if conductive, can mate the device contactor to the ground plane of the PCB, thus further enhancing noise shielding provided by the RF shield.

Additional embodiments will be set forth in part in the description which follows, and in part will be obvious from the description, or may be learned by practice of the disclosed embodiments. Embodiments will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate embodiments of the invention and together with the description, serve to explain the principles of the invention.

FIGS. 1A and 1B are top plan views of a device contactor illustrating an exemplary configuration of the device contactor with an integrated shield against RF and EM interference;

FIG. 2 illustrates a schematic cross sectional view of a device contactor with an integrated shield forming a Faraday cage, in accordance with various embodiments of the invention.

FIGS. 3A-C are schematic cross sectional views of a Faraday cage being formed using an integrated shield of a device contactor, in accordance with various embodiments of the invention;

FIGS. 4A-C are top plan views of device contactors illustrating exemplary configurations of integrated shields, in accordance with various embodiments of the invention; and

FIG. 5 is a top plan view of device contactors with a shared integrated shield, according to various embodiments of the invention.

### DETAILED DESCRIPTION

Reference will now be made in detail to the exemplary embodiments, an example of which is illustrated in the accompanying drawings. Wherever possible, the same reference numbers will be used throughout the drawings to refer to the same or like parts.

In the following description, reference is made to the accompanying drawings that form a part thereof, and in which is shown by way of illustration specific exemplary embodiments in which may be practiced. These embodiments are described in sufficient detail to enable those skilled in the art to practice these embodiments and it is to be understood that other embodiments may be utilized and that changes may be made without departing from the scope of the invention. The following description is, therefore, merely exemplary.

Notwithstanding that the numerical ranges and parameters setting forth the broad scope of the exemplary embodiments are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5.

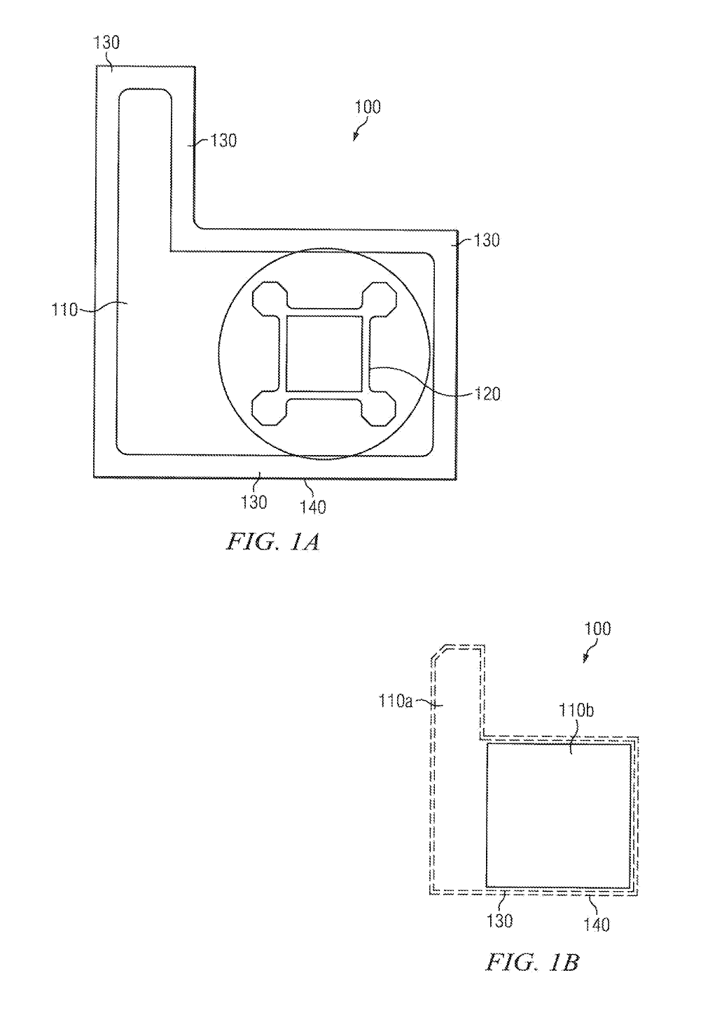

FIGS. 1A and 1B illustrate top plan views of a device contactor 100 with an integrated radio frequency (“RF”) shield 110, in accordance with various embodiments of the invention. As shown in FIG. 1A, RF shield 110 is integrated with device contactor 100, and when device contactor 100 is docked or removably attached to a printed circuit board (“PCB”), RF shield 110 provides a Faraday cage for a device 120 under test and/or its associated circuitry against external RF and electromagnetic (“EM”) interference. RF shield 110 can also shield device 100 under test from its associated circuitry, and vice versa. In various embodiments, such as those shown in FIGS. 1A and 1B, device contactor 100 hosts one device 120 under test. In other embodiments, device contactor 100 can host multiple devices under test, and RF shield 110 can shield the devices and their associated circuitry from external RF and EM interference, the devices from their associated circuitry and vice versa, and/or the devices from one another. Device contactor 100, including RF shield 110, can be made of a conductive material(s), such as metals and metal alloys, semimetals (e.g., graphite), conductive polymers, and the like. Device contactor 100 can also be made of other types of material, such as plastic, ceramic, anodized metal, and the like, and can contain or be coated with conductive materials.

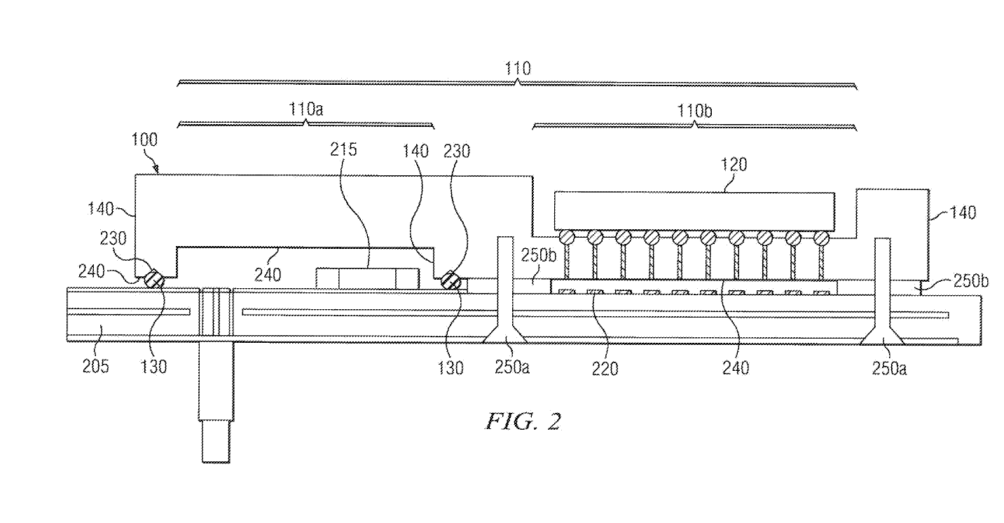

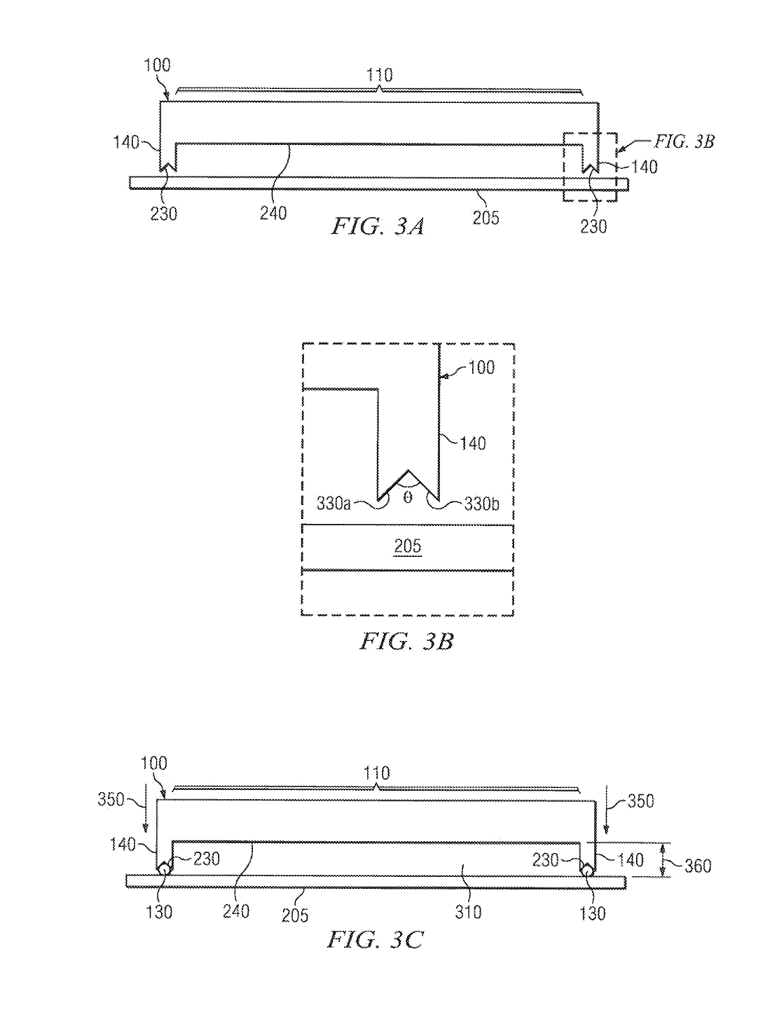

In various embodiments, a shield gasket 130 can be attached or coupled to device contactor 100. Shield gasket 130 can include a compressible RF gasket material operationally attached to a PCB-facing surface of device contactor 100, to form a more complete seal between RF shield 110 and the PCB when device contactor 100 is docked or attached to the PCB. In doing so, shield gasket 130 can seal off most if not all possible entry points for external radiation, thus working in conjunction with RF shield 110 to form a Faraday cage that shields device 120 under test and its associated circuitry from external RF and EM radiation. Shield gasket 130 can be adhered using a conductive adhesive, attached, or coupled to a PCB-facing surface of device contactor 100. Shield gasket 130 can also be housed or seated in grooves machined in a PCB-facing surface of device contactor 100, examples of which are shown in FIGS. 2 and 3A-C and further described infra.

As shown in FIGS. 1A, 1B, 3A-C, and 4A-C, shield gasket 130 can be coupled to device contactor 100 along or near a periphery 140 to circumscribe the PCB-facing surface of device contactor 100, thus maximizing the volume of the Faraday cage formed therefrom. Other configurations of shield gasket 130 are possible without departing from the scope of the invention. For example, shield gasket 130 can be coupled to device contactor 100 through an interior of the PCB-facing surface of device contactor 100, such as between device 120 and its associated circuitry, away from periphery 140, to isolate device 120 from its associated circuitry and vice versa. For another example, in various embodiments in which device contactor 100 can host multiple devices under test, shield gasket 130 can be coupled to device contactor 100 in various configurations to minimize cross-talk by shielding the devices from one another and/or their associated circuitry.

By operationally attaching shield gasket 130 to device contactor 100, shield gasket 130 becomes reusable for testing other devices. When device contactor 100 is removed from the PCB, shield gasket 130 remains attached or coupled to device contactor 100 instead of the PCB. Shield gasket 130 can also be made of a conductive material(s) so that when device contactor 100 is docked or removably attached to the PCB, shield gasket 130 can electrically mate RF shield 110 to the ground plane of the PCB. Shield gasket 130 can be made of a compressible conductive material(s) such as conductive elastomers, compressible resins, filled plastics, knitted wire mesh, fabric over foam, and the like. Different RF gasket materials can be used for shield gasket 130 to achieve varying levels of RF shielding and isolation.

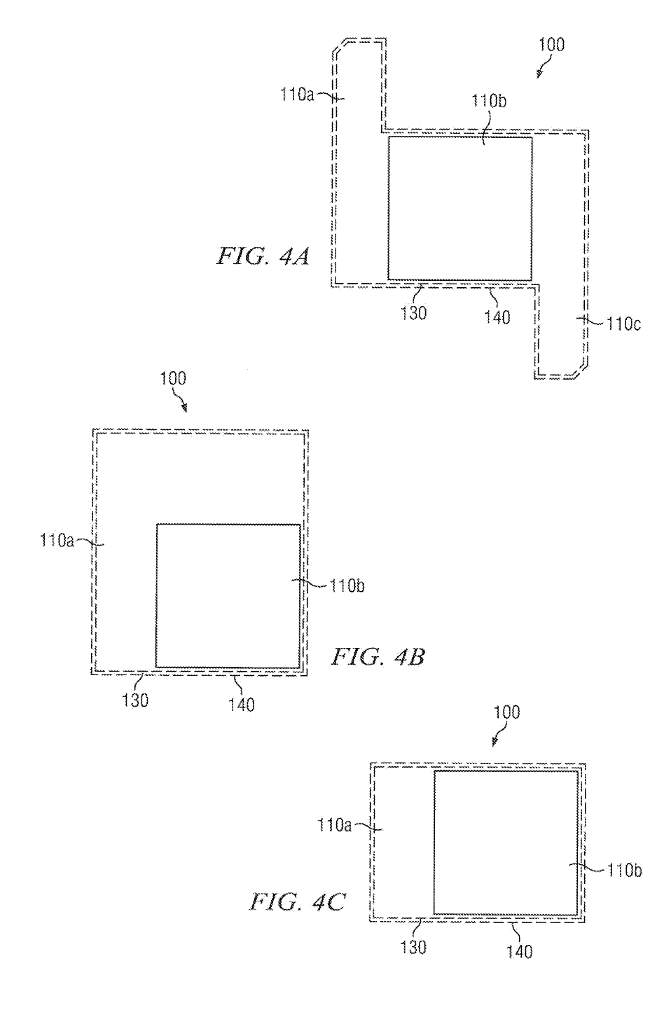

In various embodiments, examples of which are shown in FIGS. 1B and 4A-C, RF shield 110 of device contactor 100 can include an extended pocket 110a and a device pocket 110b. In a further example as shown in FIG. 4A, device contactor 100 can include a second extended pocket 110c. Device pocket 110b can provide RF shielding for device 120 under test and/or its associated circuitry and components. Extended pocket 110a and second extended pocket 110c can provide RF shielding for circuitry and components associated with device 120 under test. In configurations as shown in FIGS. 1A, 1B and 4A-C, shield gasket 130 is attached to device contactor 100 along or near the outer edges, or periphery 140, of a PCB-facing surface of device contactor 100, which would maximize the volume of the Faraday cage provided by RF shield 110. Other configurations of RF shield 110 are possible without departing from the scope of the invention. For example, in further configurations, shield gasket 130 can be attached to device contactor 100 through an interior of the PCB-facing surface of device contractor 100, to shield a device under test from its associated circuitry and vice versa, or if device contactor 100 hosts multiple devices under test, to minimize cross-talk by shielding the devices from one another and/or their associated circuitry.

FIG. 2 illustrates a schematic cross sectional view of device contactor 100 with integrated RF shield 110, in accordance with various embodiments of the invention. As shown in FIG. 2, RF shield 110 can include extended pocket 110a and device pocket 110b. When device contactor 100 is docked or removably attached to a PCB 205, such as a load board or a test board, RF shield 110 can provide one or more Faraday cages for device 120 under test and/or its associated circuitry, such as a component 215 and a circuit pattern 220, against external RF and EM interference. In various embodiments, an example of which is shown in FIG. 2, RF shield 110 can isolate device 120 under test from its associated circuitry, thus shielding device 120 from its associated circuitry and vice versa. In further embodiments, RF shield 110 can provide a Faraday cage that shields device 120 and its associated circuitry from external RF and EM interference, but does not shield device 120 from its associated circuitry or vice versa. In further embodiments, RF shield 110 can provide a Faraday cage that shields device 120 and its associated circuitry from external RF and EM interference, and also shields device 120 from its associated circuitry and vice versa. In other embodiments, device contactor 100 can host multiple devices under test, and RF shield 110 can shield the devices and their associated circuitry from external RF and EM interference, the devices from their associated circuitry and vice versa, and/or the devices from one another.

According to various embodiments, an example of which is shown in FIG. 2, device contactor 100 can include one or more grooves 230 located on a PCB-facing surface 240 of device 100 to house and/or seat shield gasket 130. Device contactor 100 can be coupled, attached, fastened, docked, or affixed to PCB 205 using means known to one skilled in the art, such as one or more fasteners 250a and bosses 250b as shown in FIG. 2. According to various embodiments, when device contactor 100 is coupled to PCB 205, shield gasket 130 can compress between device contactor 100 and PCB 205 to seal gaps and/or form a good ground connection between device contactor 100 and PCB 205.

FIGS. 3A-C are schematic cross sectional views of a Faraday cage 310 being formed using integrated RF shield 110 of device contactor 100, in accordance with various embodiments of the invention. Device contactor 100 can include grooves 230 to house and/or seat shield gasket 130. Grooves 230 can be machined, scored, etched, stamped, or formed on PCB-facing surface 240 of device contactor 100. A profile of grooves 230 can have a concave shape. For instance, grooves 230 can have a V-shaped or a semi-circular profile. According to various embodiments, such as those shown in FIGS. 3A-C, a profile of grooves 230 is V-shaped, such that edges 330a and 330b meet at a vertex at an angle θ. Angle θcan be greater than 0° and less than 180°, such as, for example, substantially equal to 45°. Grooves 230 can be located on PCB-facing surface 240 adjacent to or near the outer edges (e.g., periphery 140), thus maximizing the volume of Faraday cage 310 formed therefrom. Grooves 230 can also be located through an interior of PCB-facing surface 240, to shield a device under test from its associated circuitry and vice versa, or if device contactor 100 can host multiple devices under test, to minimize cross-talk by shielding the devices from one another and/or their associated circuitry.

When device contactor 100 is coupled to PCB 205, compressive force 350 can be applied to device contactor 100 such that shield gasket 130 is compressed between device contactor 100 and PCB 205, thus sealing gaps and/or forming a ground connection between device contactor 100 and PCB 205. In various embodiments, examples of which are illustrated in FIGS. 2 and 3C, shield gasket 130 can be housed or seated in grooves 230, such that compressive force 350 causes shield gasket 130 to compress at least partially within grooves 230. Furthermore, when device contactor 100 that incorporates shield gasket 130 is coupled to PCB 205, an inside component height allowance 360 provided by device contactor 100 can be substantially the same as that provided by a device contactor that does not incorporate shield gasket 130.

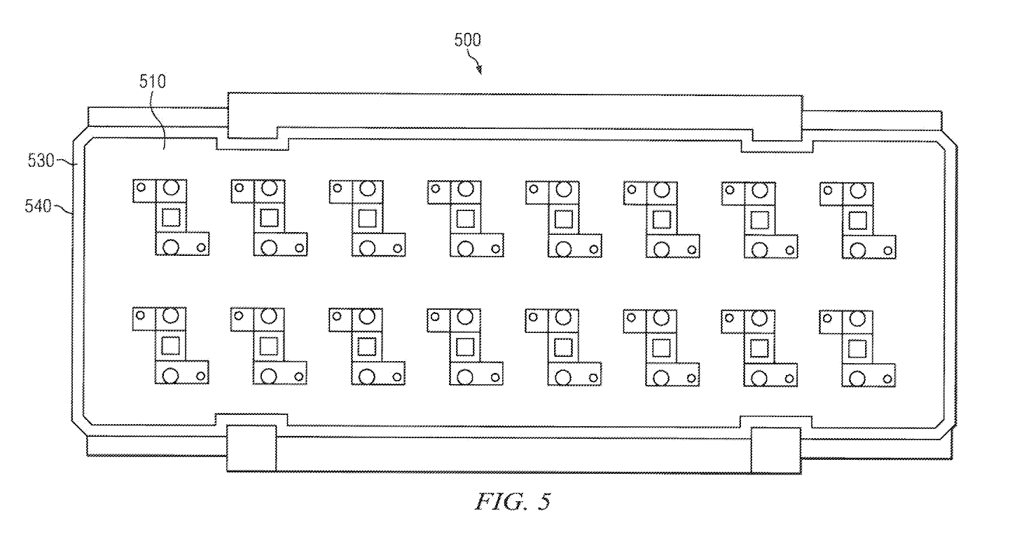

FIG. 5 is a top plan view of a device contactor 500 capable of hosting multiple devices under test that includes a shared integrated shield 510 for the devices under test, according to various embodiments of the invention. A shield gasket 530 can be coupled to device contactor 500 along or near a periphery 540 to circumscribe a PCB-facing surface of device contactor 500, thus maximizing the volume of the Faraday cage formed therefrom to shield the devices under test from external RF and EM interference. Other configurations of shield gasket 530 are possible without departing from the scope of the invention. For example, to minimize cross-talk, shield gasket 530 can be coupled to device contactor 500 through an interior of the PCB-facing surface of device contactor 500, such as between the devices and/or their associated circuitry, away from periphery 540, to isolate the devices from their associated circuitry and vice versa, and/or shield the devices from one another.

Other embodiments of the present teaching will be apparent to those skilled in the art from consideration of the specification and practice of the exemplary embodiments disclosed herein. It is intended that the specification and examples be considered as exemplary only, with a true scope and spirit of the invention being indicated by the following claims.

What is claimed is:

1. An apparatus, comprising:
a device contactor comprising a radio frequency (“RF”) shield;
a gasket coupled to a first surface of the device contactor,
wherein when the device contactor is removably attached to a printed circuit board (“PCB”), the gasket contacts the PCB, and the RF shield and the gasket form a Faraday cage for at least one of a device under test or circuitry associated with the device under test.

2. The apparatus of claim 1, wherein the device contactor includes one or more grooves on the first surface, wherein the gasket is housed at least partially within the one or more grooves.

3. The apparatus of claim 2, wherein the one or more grooves circumscribe a periphery of the first surface of the device contactor.

4. The apparatus of claim 2, wherein the one or more grooves are located on the first surface away from a periphery of the first surface of the device contactor.

5. The apparatus of claim 2, wherein a profile of the one or more grooves has a concave shape.

6. The apparatus of claim 1, wherein when the device contactor is attached to the PCB, the Faraday cage shields at least one of the device under test or the circuitry associated with the device under test from external RF radiation.

7. The apparatus of claim 1, wherein when the device contactor is attached to the PCB, the Faraday cage shields the device under test from RF radiation generated by the circuitry associated with the device under test.

8. The apparatus of claim 1, wherein when the device contactor is attached to the PCB, the Faraday cage shields the circuitry associated with the device under test from RF radiation generated by the device under test.

9. The apparatus of claim 1, wherein the device contactor hosts a plurality of devices under test, and wherein when the device contactor is attached to the PCB, the Faraday cage shields a first device of the plurality of devices under test from RF radiation generated by a second device of the plurality of devices under test.

10. The apparatus of claim 1, wherein the gasket comprises a conductive material.

11. The apparatus of claim 10, wherein the gasket electrically couples the device contactor to a ground plane of the PCB when the device contactor is attached to the PCB.

12. The apparatus of claim 1, wherein the gasket comprises a compressible material.

13. The apparatus of claim 12, wherein when the device contactor is attached to the PCB, the gasket is compressed between the device contactor and the PCB.

14. The apparatus of claim 12, wherein the gasket comprises at least one of an elastomer, a compressible resin, a filled plastic, a knitted wire mesh, or a fabric over foam.

15. The apparatus of claim 1, wherein the device contactor comprises at least one of a metal, a metal alloy, a semimetal, or a conductive polymer.

16. An apparatus, comprising:
a device contactor comprising a radio frequency (“RF”) shield;
a gasket coupled to a first surface of the device contactor, the gasket comprising a conductive material,
wherein when the device contactor is removably attached to a printed circuit board (“PCB”), the gasket contacts the PCB and compresses between the device contactor and the PCB, and the RF shield and the gasket form a Faraday cage for at least one of a device under test or circuitry associated with the device under test.

17. The apparatus of claim 16, wherein the device contactor includes one or more grooves on the first surface, wherein the gasket is housed at least partially within the one or more grooves.

18. The apparatus of claim 17, wherein the one or more grooves circumscribe a periphery of the first surface of the device contactor.

19. The apparatus of claim 17, wherein the one or more grooves are located on the first surface away from a periphery of the first surface of the device contactor.

20. The apparatus of claim 17, wherein a profile of the one or more grooves has a concave shape.
